(19) United States
(12) Patent Application Publication
(10) Pub. No.: US 2006/0194058 A1
(43) Pub. Date: Aug. 31, 2006

(54) Uniform single walled carbon nanotube network

(76) Inventors: Islamshah S. Amlani, Chandler, AR (US); Larry A. Nagahara, Phoenix, AZ (US)

Correspondence Address: INGRASSIA FISHER & LORENZ, P.C., 7150 E. CAMELBACK, STE. 325, SCOTTSDALE, AZ, 85251, US

(21) Appl. No.: 11/065,935

(22) Filed: Feb. 25, 2005

(51) Int. Cl. H01L 31/0328; B32B 9/00; B05D 5/12; B05D 3/10

(52) U.S. Cl. 428/408; 257/192; 428/447; 427/58; 427/122; 427/301

(57) ABSTRACT

An apparatus (50) and method is provided for growing a network of common diameter nanotubes (24). The apparatus comprises chemically functionalizing a portion (16) of a substrate (12); anchoring catalyst nanoparticles (22), each having substantially the same diameter, on the portion (16) of the substrate (12); and growing overlapping carbon nanotubes (24), each having substantially the same diameter, on the catalyst nanoparticles (22).

### FIELD OF THE INVENTION

The present invention generally relates to a carbon nanotubes and more particularly to a network of single walled carbon nanotubes.

### BACKGROUND OF THE INVENTION

Carbon is one of the most important known elements and can be combined with oxygen, hydrogen, nitrogen and the like. Carbon has four known unique crystalline structures including diamond, graphite, fullerene and carbon nanotubes. In particular, carbon nanotubes refer to a helical tubular structure grown with a single wall or multi-wall, and commonly referred to as single-walled nanotubes (SWNTs), or multi-walled nanotubes (MWNTs), respectively. These types of structures are obtained by rolling a sheet formed of a plurality of hexagons. The sheet is formed by combining each carbon atom thereof with three neighboring carbon atoms to form a helical tube. Carbon nanotubes typically have a diameter in the order of a fraction of a nanometer to a few hundred nanometers.

Carbon nanotubes can function as either a conductor, like metal, or a semiconductor, according to the rolled shape and the diameter of the helical tubes. With metallic-like nanotubes, it has been found that a one-dimensional carbon-based structure can conduct a current at room temperature with essentially no resistance. Further, electrons can be considered as moving freely through the structure, so that metallic-like nanotubes can be used as ideal interconnects. When semiconductor nanotubes are connected to two metal electrodes, the structure can function as a field effect transistor wherein the nanotubes can be switched from a conducting to an insulating state by applying a voltage to a gate electrode. It has been shown that carbon nanotubes yield a transconductance per unit channel width greater than that of silicon transistors. Therefore, carbon nanotubes are potential building blocks for nanoelectronic devices because of their unique structural, physical, and chemical properties.

Existing methods for the production of nanotubes, include arc-discharge and laser ablation techniques. These methods typically yield bulk materials with bundles of nanotubes. Recently, reported by J. Kong, A. M. Cassell, and H Dai, in Chem. Phys. Lett. 292, 567 (1988) and J. Hafner, M. Bronikowski, B. Azamian, P. Nikoleav, D. Colbert, K. Smith, and R. Smalley, in Chem. Phys Lett. 296, 195 (1998) was the formation of high quality individual single-walled carbon nanotubes (SWNTs) demonstrated via thermal chemical vapor deposition (CVD) approach, using Fe/Mo or Fe nanoparticles as a catalyst. The CVD process has allowed selective growth of individual SWNTs, and simplified the process for making SWNT based devices. Typically, the choice of catalyst materials that can be used to promote SWNT growth in a CVD process comprises iron, cobalt, and nickel particles.

A network of nanotubes has been shown as a field effect transistor by placing source and drain electrodes at opposed sides of the network and a gate electrode positioned adjacent the nanotubes therebetween. The network of nanotubes has obvious advantages since it allows multiple current paths. The nanotube network acts like a semiconducting channel even if some of the nanotubes in the network are metallic as long as they do not short out the entire channel. A network of carbon nanotubes are easily produced by growth on a catalyzed substrate or by suspending a substrate in a solution of carbon nanotubes. However, results are poor due to the inconsistency in nanotube diameter and density. The physical and chemical properties of carbon nanotubes vary with their diameter (current carrying capability) and helicity (determines whether metallic or semiconductor). Different nanotube diameters result in variable bandgaps of individual nanotubes leading to non-uniform electrical properties of the nanotube network.

Accordingly, it is desirable to provide a carbon nanotube network having improved electrical consistency. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

An apparatus and method is provided for growing a network of common diameter nanotubes. The apparatus comprises chemically functionalizing a portion of a substrate; anchoring catalyst nanoparticles, each having substantially the same diameter, on the portion of the substrate; and growing overlapping carbon nanotubes, each having substantially the same diameter, on the catalyst nanoparticles.

### BRIEF DESCRIPTION OF THE DRAWINGS

The present invention will hereinafter be described in conjunction with the following drawing figures, wherein like numerals denote like elements, and

FIGS. 1-3 are a top view and cross sections of a structure being prepared for the growth of carbon nanotubes;

FIG. 4 is the structure of FIG. 2 having catalytic nanoparticles positioned thereon in accordance with a first embodiment of the present invention;

FIG. 5 is an isometric view of the structure of FIG. 4 having carbon nanotubes grown thereon in accordance with the first embodiment of the present invention;

FIG. 6 is an isometric view of the first embodiment of FIG. 4 having conducting electrodes deposited thereon;

FIG. 7 is a cut-away isometric view of a second embodiment of the present invention; and

FIG. 8 is a block diagram of a third embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

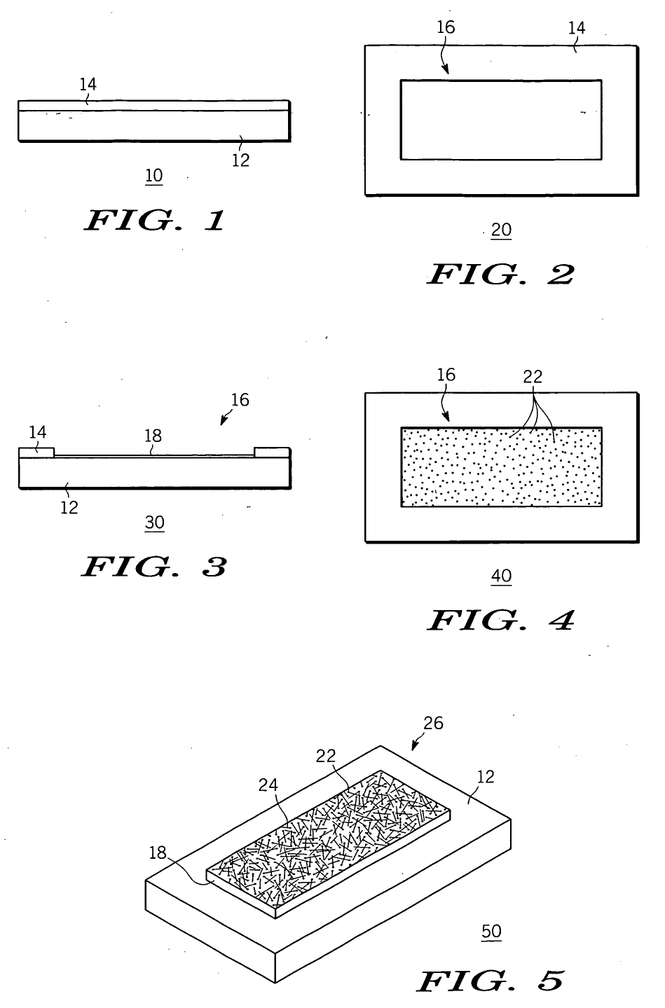

Referring to FIG. 1, a resist 14 is formed on a substrate 12 of the device 10. The substrate 12 preferably comprises silicon dioxide on silicon, but may alternatively comprise, for example, glass, ceramic or a flexible substrate. The resist would comprise any resist typically used in the semiconductor industry. Optionally, the layer 18 may be formed by a stamping technique known to those skilled in the industry without using the resist 14, as discussed below.

Referring to FIG. 2, some of the resist 14 is lifted, e.g., by a photo etch, to expose a portion 16 of the substrate 12. While only one portion 16 of the substrate 12 is exposed in the device 20 of FIG. 2, it should be understood that many portions 16, perhaps many thousands or more, could exist on a single substrate 12.

Referring to FIG. 3, the portion 16 is chemically functionalized by exposing to radiation, or submerging the device 20 in a wet solution, or exposing to a vapor, of aminopropyltriethoxysilane (APS), thereby forming a layer 18 on the portion 16 of the substrate 12. While APS is the preferred solution, any chemical or multilayers of chemicals that create a charged surface on the substrate to allow electrostatic interaction with the oppositely charged catalytic nanoparticles. The electrostatic interaction between the chemically functionalized surface and the nanoparticles will immobilize the nanoparticles in the selected region. The layer 18 would have a thickness, for example, in the range of 5.0 to 1000 Angstroms.

Referring to FIG. 4, catalyst nanoparticles 22 of a fixed diameter are anchored on the layer 18 by submerging the device 30 in a wet solution containing the catalyst nanoparticles 22. APS has an affinity (an electrostatic attraction) for the catalyst nanoparticles 22. The catalyst nanoparticles 22 preferably comprise nickel, iron, cobalt, or any combination thereof, but could comprise any one of a number of other materials including a transition metal or alloys thereof, for example, Fe/Co, Ni/Co or Fe/Ni. The wet solution containing the catalyst nanoparticles 22 may comprise any solvent that allows monodisperse suspension of the catalytic nanoparticles. The nanoparticles would have a diameter in the range of 0.5 nanometers to 5 nanometers, but preferably would be approximately 1.0 to 2.0 nanometers thick for transistor or sensor applications discussed later. The resist 14 is then removed by either a wet or dry etch. Alternatively, the resist 14 may be removed prior to submerging the device 30 in the wet solution.

Referring to FIG. 5, a chemical vapor deposition (CVD) is performed by exposing the device 40 to hydrogen (H₂) and a carbon containing gas, for example methane (CH₄), between 450° C. and 1000° C., but preferably at 850° C. CVD is the preferred method of growth because the variables such as temperature, gas input, and catalyst may be controlled. Carbon nanotubes 24 are thereby grown from the nanoparticles 22 forming a network 26 of connected carbon nanotubes 24. Although only a few carbon nanotubes 24 are shown, those skilled in the art understand that a large number of carbon nanotubes 24 could be grown. By using nanoparticles 22 having a common diameter, the nanotubes 24 will grow with a similar common diameter. The desired diameter of the carbon nanotubes may be selected by depositing catalytic nanoparticles 22 having the desired diameter. The carbon nanotubes 24 may grow as either a metallic or semiconducting. The nanotubes 24 may be grown in any manner known to those skilled in the art, and are typically 100 nm to 1 cm in length and less than 1 nm to 100 nm in diameter.

Referring to FIG. 6, conductive electrodes 28 are placed on the carbon nanotubes 24 at the sides of the network 26 of device 50. The conductive electrodes 28 may comprise any conductive material, but preferably would comprise layers of chromium and gold, titanium and gold, palladium, or gold. Contact between the nanotubes 24 and conductive electrodes 28 are made during fabrication, for example, by any type of lithography, e-beam, optical, soft lithography, or imprint technology.

In one embodiment, the conductive electrodes 28 of device 60 may be used as a source and a drain, respectively. A gate electrode 32 may be either buried in the substrate, for example, below the portion 16 of the substrate 12 (not shown), or it may be placed above the carbon nanotubes 24, separated therefrom by a dielectric layer 34 as shown in device 70 of FIG. 7.

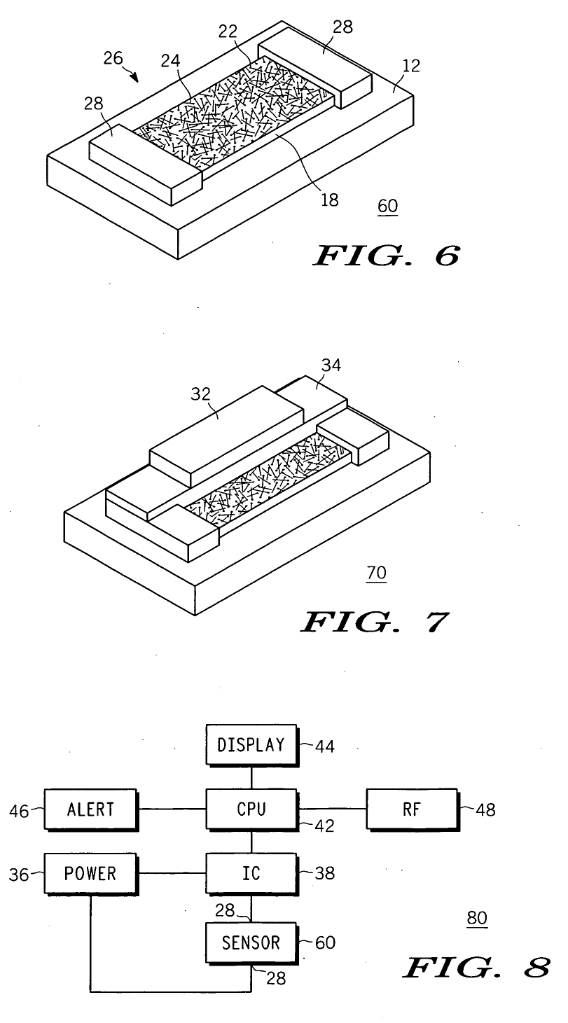

FIG. 8 illustrates an embodiment wherein the device of FIG. 6 is used as a sensor. For example, when a molecule attaches itself to a nano-structure, such as the carbon nanotube 24, a characteristic of the material changes, such as the change in a current flowing in the nanotube 24 that is measurable in a manner known to those skilled in the art. By measuring this change in the current, it is known that a determination may be made as to the number of molecules that have attached to the carbon nanotube 24, and therefore, a correlation to the concentration of the molecules in the environment around the carbon nanotube 24. Additionally, the nano-structure may be coated with a substance for determining specific environmental agents. And while a change in current is the preferred embodiment for the measurable material characteristic, other embodiments would include, for example, magnetic, optical, frequency, and mechanical. The exemplary system 80 includes the device 60, for example, having one of its electrodes 28 coupled to a power source 36, e.g., a battery. A circuit 38 determines the current between the electrodes 28 and supplies the information to a processor 42. The information may be transferred from the processor 42 to a display 44, an alert device 46, and/or an RF transmitter 48, for example.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A process for fabricating a network of carbon nanotubes comprising:
chemically functionalizing a portion of a substrate;
anchoring catalyst nanoparticles, each having substantially the same diameter, on the portion of the substrate; and
growing overlapping carbon nanotubes, each having substantially the same diameter, from the catalyst nanoparticles.

2. The process of claim 1 wherein the chemically functionalizing comprises applying aminopropyltriethoxysilane.

3. The process of claim 1 wherein the chemically functionalizing comprises forming a layer having a first charge on the substrate.

4. The process of claim 3 wherein the anchoring step comprises anchoring catalyst nanoparticles having a second charge opposite that of the first charge.

5. The process of claim 1 further comprising depositing conductive electrodes on opposed sides of the portion of the substrate, each conductive electrode coupled to the carbon nanotubes, thereby forming a current path from one electrode to the other through the carbon nanotubes.

6. The process of claim 5 further comprising forming a field effect transistor by depositing a gate electrode near the carbon nanotubes.

7. The process of claim 5 further comprising:
coupling the electrodes to a circuit;
determining when molecules have attached themselves to the carbon nanotubes.

8. A process for forming a network of carbon nanotubes, comprising:
providing a substrate;
chemically functionalizing a layer on the substrate;
forming a plurality of catalytic nanoparticles, each having substantially the same diameter, on the layer; and
growning a carbon nanotube from each of the plurality of catalyst nanoparticles in an overlapping fashion.

9. The process of claim 8 wherein the chemically functionalizing comprises applying aminopropyltriethoxysilane.

10. The process of claim 8 wherein the growing step comprises growing a carbon nanotube having a common diameter on each of the plurality of catalyst nanoparticles.

11. The process of claim 8 wherein the chemically functionalizing comprises forming a layer having a first charge on the substrate.

12. The process of claim 11 wherein the forming a plurality of catalytic nanoparticles comprises forming a plurality of catalyst nanoparticles having a second charge opposite that of the first charge.

13. The process of claim 8 further comprising depositing conductive electrodes on opposed sides of the carbon nanotubes, each conductive electrode electrically coupled to the carbon nanotubes, thereby forming a current path from one electrode to the other through the carbon nanotubes.

14. The process of claim 13 further comprising forming a field effect transistor by depositing a gate electrode near the carbon nanotubes.

15. The process of claim 13 further comprising:
coupling the electrodes to a circuit;
determining when molecules have attached themselves to the carbon nanotubes.

16. A network of carbon nanotubes comprising:
a substrate;
a chemically functional layer formed on the substrate;
a plurality of catalyst nanoparticles, each having substantially the same diameter, positioned on the chemically functionally layer; and
at least one carbon nanotube grown from each one of the plurality of catalyst nanoparticles, the carbon nanotubes lying on the chemically functional layer, overlapping in a random fashion, and having substantially the same diameter.

17. The network of claim 16 wherein the chemically functional layer comprises aminopropyltriethoxysilane.

18. The network of claim 16 wherein the chemically functional layer comprises a first charge.

19. The network of claim 18 wherein the anchoring catalyst nanoparticles comprise a second charge opposite that of the first charge.

20. The network of claim 16 further comprising conductive electrodes on opposed sides of the portion of the substrate, each conductive electrode coupled to the carbon nanotubes, thereby forming a current path from one electrode to the other through the carbon nanotubes.

21. The network of claim 20 further comprising a gate electrode near the carbon nanotubes, wherein the conductive electrodes and the gate electrode form a field effect transistor.

22. The network of claim 20 further comprising:
a power source coupled to the circuit;
a circuit coupled to the electrodes for sensing when molecules have attached themselves to the carbon nanotubes.
